(19) United States
(12) Patent Application Publication
(10) Pub. No.: US 2025/0244388 A1
(43) Pub. Date: Jul. 31, 2025

(54) METHOD AND APPARATUS WITH BATTERY STATE ESTIMATION

(71) Applicant: SAMSUNG ELECTRONICS CO., LTD., Suwon-si (KR)

(72) Inventor: Jinho KIM, Suwon-si (KR)

(73) Assignee: SAMSUNG ELECTRONICS CO., LTD., Suwon-si (KR)

(21) Appl. No.: 18/953,563

(22) Filed: Nov. 20, 2024

(30) Foreign Application Priority Data
Jan. 31, 2024 (KR) 10-2024-0015094

(51) Int. Cl. G01R 31/367; G01R 31/36; G01R 31/3835; G01R 31/396

(52) U.S. Cl. CPC G01R 31/367; G01R 31/3648; G01R 31/3835; G01R 31/396

(57) ABSTRACT

A processor-implemented method including determining an estimated voltage of a battery and a surface concentration of an anode and cathode of the battery through a battery model, determining a voltage difference between a sensed voltage of the battery and the determined estimated voltage, determining a state variation of the battery based on the determined voltage difference and each determined surface concentration, updating the battery model based on the determined state variation, and determining state information of the battery based on the updated battery model.

### CROSS-REFERENCE TO RELATED APPLICATIONS

This application claims the benefit under 35 USC § 119 (a) of Korean Patent Application No. 10-2024-0015094, filed on Jan. 31, 2024, in the Korean Intellectual Property Office, the entire disclosure of which is incorporated herein by reference for all purposes.

### BACKGROUND

### 1. Field

The following description relates to a method and apparatus with battery state estimation.

### 2. Description of Related Art

There are various ways to estimate the state of a battery or batteries. For example, the states of batteries may be estimated by integrating currents of the batteries or by using a battery model (for example, an electric circuit model or an electrochemical model).

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In a general aspect, here is provided a processor-implemented method including determining an estimated voltage of a battery and a surface concentration of an anode and cathode of the battery through a battery model, determining a voltage difference between a sensed voltage of the battery and the determined estimated voltage, determining a state variation of the battery based on the determined voltage difference and each determined surface concentration, updating the battery model based on the determined state variation, and determining state information of the battery based on the updated battery model.

The determining of the state variation may include determining a first open circuit potential (OCP) of the anode and the cathode using each determined surface concentration, determining a first open circuit voltage (OCV) of the battery using each determined first OCP,

compensating each determined surface concentration based on an initial state variation, determining a second OCP of the anode and the cathode using each compensated surface concentration, determining a second OCV of the battery using each determined second OCP, and

determining the state variation using the determined first OCV, the determined second OCV, the initial state variation, and the determined voltage difference.

The determining of the first OCP of the anode and the cathode may include determining the first OCP of the anode and the cathode using each OCP table showing a relationship between a stoichiometric concentration and an OCP of the anode and the cathode and each determined surface concentration.

The determining of the state variation using the determined first OCV, the determined second OCV, the initial state variation, and the determined voltage difference may include determining a difference value between the determined second OCV and the determined first OCV and determining the state variation by applying a ratio between the determined difference value and the determined voltage difference to the initial state variation.

The compensating of each determined surface concentration may include determining each compensation value for compensating each determined surface concentration using a predetermined value for the anode and the cathode and the initial state variation and compensating each determined surface concentration based on each determined compensation value.

The determining of the state variation may include determining an OCP of the anode and the cathode using each determined surface concentration, determining an OCV of the battery using each determined OCP, and determining an optimal value of the state variation by performing an optimization operation of optimizing the state variation based on the determined voltage difference, each determined surface concentration, and the determined OCV.

The determining of the optimal value may include performing the optimization operation by adjusting a voltage difference between the determined OCV and an OCV, considering the state variation, to be the same as the determined voltage difference.

The determining of the state variation may include obtaining a first ratio value corresponding to a first determined surface concentration of a first electrode among the anode and the cathode from a first table showing a relationship between a ratio between a concentration variation and an OCP variation of the first electrode, and a concentration of the first electrode, obtaining a second ratio value corresponding to a second determined surface concentration of a second electrode among the anode and cathode from a second table showing a relationship between a ratio between a concentration variation and an OCP variation of the second electrode, and a concentration of the second electrode, and determining the state variation using the determined voltage difference, the obtained first ratio value, the obtained second ratio value, and an initial state variation.

The determining of the state variation using the determined voltage difference, the obtained first ratio value, the obtained second ratio value, and the initial state variation may include determining a first compensation value for compensating the surface concentration of the first electrode by applying the initial state variation to a predetermined value for the first electrode, determining a first OCP variation value of the first electrode using the determined first compensation value and the obtained first ratio value, determining a second compensation value for compensating the surface concentration of the second electrode by applying the initial state variation to a predetermined value for the second electrode, determining a second OCP variation value of the second electrode using the determined second compensation value and the obtained second ratio value, calculating a sum of the determined first OCP variation value and the determined second OCP variation value, and determining the state variation by applying a ratio between the determined voltage difference and the calculated sum to the initial state variation.

The updating of the battery model may include updating an internal state of the battery model by compensating one or more of parameters of the battery model based on the determined state variation.

In a general aspect, here is provided an electronic device including a battery, at least one processor configured to execute instructions, and a memory storing the instructions, an execution of the instructions causes the at least one processor to determine an estimated voltage of the battery and a surface concentration of an anode and a cathode of the battery through a battery model, determine a voltage difference between a sensed voltage of the battery and the determined estimated voltage, determine a state variation of the battery based on the determined voltage difference and each determined surface concentration, update the battery model based on the determined state variation, and determine state information of the battery based on the updated battery model.

The electronic device may include a voltage sensor configured to sense the battery to obtain the sensed voltage of the battery.

The execution of the instructions may cause the at least one processor to determine a first open circuit potential (OCP) of the anode and the cathode using each determined surface concentration, determine a first open circuit voltage (OCV) of the battery using each determined first OCP, compensate each determined surface concentration based on an initial state variation, determine a second OCP of the anode and the cathode using each compensated surface concentration, determine a second OCV of the battery using each determined second OCP, and determine the state variation using the determined first OCV, the determined second OCV, the initial state variation, and the determined voltage difference.

The execution of the instructions may cause the at least one processor to determine the first OCP of the anode and the cathode using each OCP table showing a relationship between a stoichiometric concentration and an OCP of the anode and the cathode and each determined surface concentration.

The execution of the instructions may cause the at least one processor to determine a difference value between the determined second OCV and the determined first OCV, and determine the state variation by applying a ratio between the determined difference value and the determined voltage difference to the initial state variation.

The execution of the instructions may cause the at least one processor to determine each compensation value for compensating each determined surface concentration using a predetermined value for the anode and the cathode and the initial state variation and compensate each determined surface concentration based on each determined compensation value.

The execution of the instructions may cause the at least one processor to obtain a first ratio value corresponding to a first determined surface concentration of a first electrode among the anode and the cathode from a first table showing a relationship between a ratio between a concentration variation and an OCP variation of the first electrode, and a concentration of the first electrode, obtain a second ratio value corresponding to a second determined surface concentration of a second electrode among the anode and the cathode from a second table showing a relationship between a ratio between a concentration variation and an OCP variation of the second electrode, and a concentration of the second electrode, and determine the state variation using the determined voltage difference, the obtained first ratio value, the obtained second ratio value, and the initial state variation.

The execution of the instructions may cause the at least one processor to determine an OCP of the anode and the cathode using each determined surface concentration, determine an OCV of the battery using each determined OCP, and determine an optimal value of the state variation by performing an optimization operation of optimizing the state variation based on the determined voltage difference, each determined surface concentration, and the determined OCV.

The execution of the instructions may cause the at least one processor to perform the optimization operation by adjusting a voltage difference between the determined OCV and an OCV, considering the state variation, to be the same as the determined voltage difference.

The execution of the instructions may cause the at least one processor to control a display such that the determined state information is displayed regarding one or more of the anode and the cathode.

Other features and aspects will be apparent from the following detailed description, the drawings, and the claims.

### BRIEF DESCRIPTION OF THE DRAWINGS

FIGS. 1 and 2 illustrate example battery systems according to one or more embodiments.

FIG. 3 illustrates an example method of estimating a battery state according to one or more embodiments.

FIGS. 4 and 5 illustrate example illustrations of determining a state variation of a battery according to one or more embodiments.

FIG. 6 illustrates an example method of determining a state variation of a battery according to one or more embodiments.

FIGS. 7A, 7B, and 8 illustrate example illustrations of determining a state variation of a battery according to one or more embodiments.

FIG. 9 illustrates an example illustration of determining an initial state variation of a battery state according to one or more embodiments.

FIG. 10 illustrates an example battery state estimation apparatus according to one or more embodiments.

FIG. 11 illustrates an example electronic device including a battery state estimation apparatus according to one or more embodiments.

FIG. 12 illustrates an example mobile device according to one or more embodiments.

Throughout the drawings and the detailed description, unless otherwise described or provided, the same drawing reference numerals may be understood to refer to the same or like elements, features, and structures. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences within and/or of operations described herein are merely examples, and are not limited to those set forth herein, but may be changed as will be apparent after an understanding of the disclosure of this application, except for sequences within and/or of operations necessarily occurring in a certain order. As another example, the sequences of and/or within operations may be performed in parallel, except for at least a portion of sequences of and/or within operations necessarily occurring in an order, e.g., a certain order. Also, descriptions of features that are known after an understanding of the disclosure of this application may be omitted for increased clarity and conciseness.

The features described herein may be embodied in different forms, and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application.

Throughout the specification, when a component or element is described as being “on”, “connected to,” “coupled to,” or “joined to” another component, element, or layer it may be directly (e.g., in contact with the other component or element) “on”, “connected to,” “coupled to,” or “joined to” the other component, element, or layer or there may reasonably be one or more other components, elements, layers intervening therebetween. When a component or element is described as being “directly on”, “directly connected to,” “directly coupled to,” or “directly joined” to another component or element, there can be no other elements intervening therebetween. Likewise, expressions, for example, “between” and “immediately between” and “adjacent to” and “immediately adjacent to” may also be construed as described in the foregoing.

Although terms such as “first,” “second,” and “third”, or A, B, (a), (b), and the like may be used herein to describe various members, components, regions, layers, or sections, these members, components, regions, layers, or sections are not to be limited by these terms. Each of these terminologies is not used to define an essence, order, or sequence of corresponding members, components, regions, layers, or sections, for example, but used merely to distinguish the corresponding members, components, regions, layers, or sections from other members, components, regions, layers, or sections. Thus, a first member, component, region, layer, or section referred to in the examples described herein may also be referred to as a second member, component, region, layer, or section without departing from the teachings of the examples.

The terminology used herein is for describing various examples only and is not to be used to limit the disclosure. The articles “a,” “an,” and “the” are intended to include the plural forms as well, unless the context clearly indicates otherwise. As non-limiting examples, terms “comprise” or “comprises,” “include” or “includes,” and “have” or “has” specify the presence of stated features, numbers, operations, members, elements, and/or combinations thereof, but do not preclude the presence or addition of one or more other features, numbers, operations, members, elements, and/or combinations thereof, or the alternate presence of an alternative stated features, numbers, operations, members, elements, and/or combinations thereof. Additionally, while one embodiment may set forth such terms “comprise” or “comprises,” “include” or “includes,” and “have” or “has” specify the presence of stated features, numbers, operations, members, elements, and/or combinations thereof, other embodiments may exist where one or more of the stated features, numbers, operations, members, elements, and/or combinations thereof are not present.

Unless otherwise defined, all terms, including technical and scientific terms, used herein have the same meaning as commonly understood by one of ordinary skill in the art to which this disclosure pertains and based on an understanding of the disclosure of the present application. Terms, such as those defined in commonly used dictionaries, are to be interpreted as having a meaning that is consistent with their meaning in the context of the relevant art and the disclosure of the present application and are not to be interpreted in an idealized or overly formal sense unless expressly so defined herein. The use of the term “may” herein with respect to an example or embodiment, e.g., as to what an example or embodiment may include or implement, means that at least one example or embodiment exists where such a feature is included or implemented, while all examples are not limited thereto.

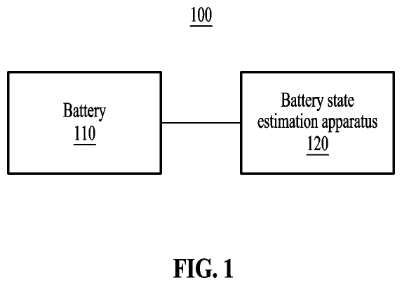

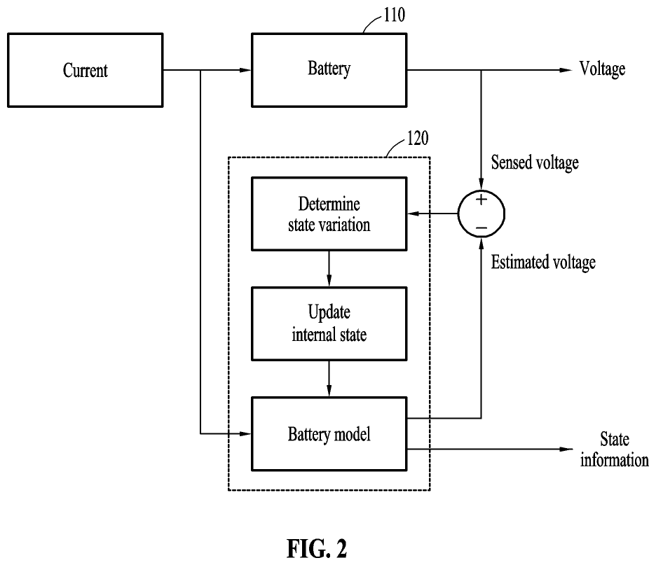

FIGS. 1 and 2 illustrate example battery systems according to one or more embodiments.

Referring to FIG. 1, in a non-limiting example, a battery system 100 may include a battery 110 and a battery state estimation apparatus 120. While FIG. 1 shows a single battery 110, this is an example, and the battery system 100 may include two or more batteries.

In an example, the battery 110 may be a battery cell, a battery module, or a battery pack.

In an example, battery state estimation apparatus 120 may sense the battery 110 using one or more sensors (e.g., one or more of a voltage sensor, a current sensor, and a temperature sensor). In other words, the battery state estimation apparatus 120 may collect sensing data obtained by sensing or measuring data about the battery 110 (i.e., sensing data). The sensing data may include voltage data, current data, and/or temperature data of the battery 110.

The battery state estimation apparatus 120 may determine (or estimate) state information of the battery 110 based on the sensing data. The state information of the battery 110 may include, in an example, a state of charge (SOC), a state of health (SOH), and/or abnormality state information. A battery model used to estimate the state information may be an electrochemical model.

Referring to FIG. 2, in a non-limiting example, state information may be estimated using a battery model.

The battery state estimation apparatus 120 may estimate the state information of the battery 110 using a battery model (e.g., an electrochemical model). The electrochemical model may be a model that estimates state information of a battery by modeling an internal physical phenomenon, such as a potential or an ion concentration distribution, of the battery.

The battery state estimation apparatus 120 may determine a voltage difference between a sensed voltage of the battery 110 measured by a sensor and an estimated voltage of the battery 110 estimated by the battery model. The battery state estimation apparatus 120 may determine a state variation of the battery 110 using the determined voltage difference dV or ΔV. The state variation may include, for example, a SOC variation d_SOC. The battery state estimation apparatus 120 may update an internal state of the battery model based on the state variation of the battery 110. The battery state estimation apparatus 120 may determine (or estimate) state information of the battery 110 based on the updated internal state of the battery model. In an example, the battery state estimation apparatus 120 may determine or estimate the state information of the battery with a high accuracy without increasing model complexity (e.g., complexity of the battery model) and a computation amount required by the battery model, through a feedback structure that determines the state variation of the battery 110 such that the voltage difference between the sensed voltage of the battery 110 and the estimated voltage estimated by the battery model is minimized, and updates the internal state of the battery model through the determined state variation.

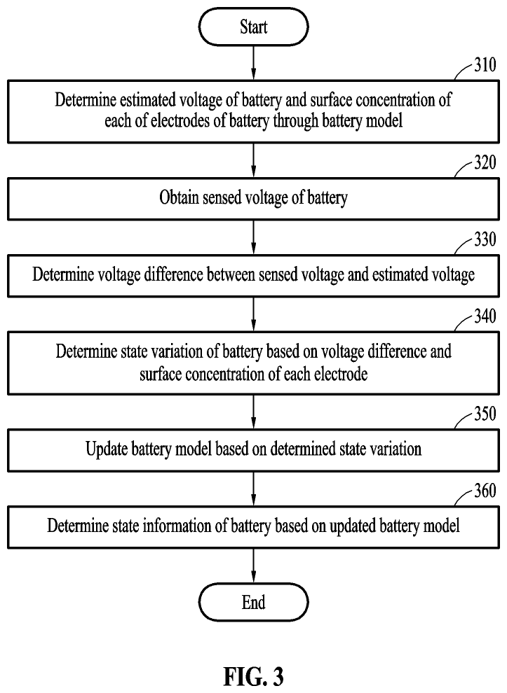

FIG. 3 illustrates an example method of estimating a battery state according to one or more embodiments.

Referring to FIG. 3, in a non-limiting example, in operation 310, a battery state estimation apparatus (i.e, the battery state estimation apparatus 120) may determine an estimated voltage Vₑₛₜ of a battery (i.e., the battery 110) and a surface concentration of each of electrodes of the battery through the battery model. The surface concentration of each of the electrodes may represent, in an example, a concentration (or an ion concentration) of an active material on the surface of each electrode of the battery. A unit of the concentration may be, for example, mol/m³, but examples are not limited thereto. While the determining of the surface concentration refers to each of the electrodes of the batteries, fewer than each electrode may be considered, in an example, to determine the concentration of active material on the surface of the electrodes of the battery. That is the determining may include sensing data from one or more of an anode electrode and one or more of a cathode electrode in an example where the battery may include one or more anode electrodes and/or cathode electrodes. However, each of the electrodes may refer to the anode and the cathode of the battery. The estimated voltage Vₑₛₜ of the battery may be calculated by the battery state estimation apparatus through the battery model, and may thus be represented as a calculated voltage of the battery.

In operation 320, the battery state estimation apparatus (i.e, the battery state estimation apparatus 120) may obtain a sensed voltage Vₛₑₙ of the battery (i.e., the battery 110). In an example, the battery state estimation apparatus may obtain the sensed voltage Vₛₑₙ of the battery using a voltage sensor.

In operation 330, the battery state estimation apparatus (i.e, the battery state estimation apparatus 120) may determine a voltage difference dV or ΔV between the sensed voltage Vₛₑₙ of the battery (i.e., the battery 110) and the estimated voltage Vₑₛₜ of the battery. The voltage difference dV or ΔV may be, for example, “the sensed voltage Vₛₑₙ−the estimated voltage Vₑₛₜ”. According to the implementation, the voltage difference may be “the estimated voltage Vₑₛₜ−the sensed voltage Vₛₑₙ”.

In operation 340, the battery state estimation apparatus (i.e, the battery state estimation apparatus 120) may determine the state variation d_SOC of the battery (i.e., the battery 110) based on the voltage difference dV and the surface concentration of each electrode.

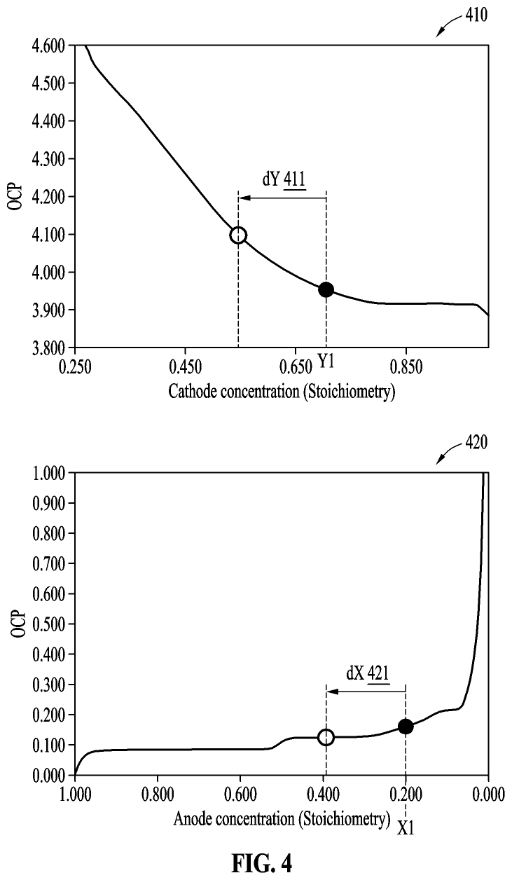

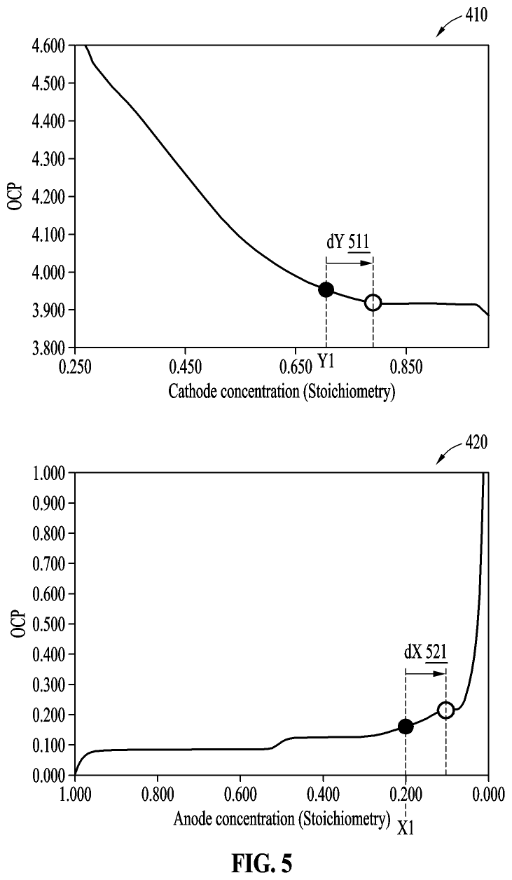

As will be described below in greater detail with reference to FIGS. 4 and 5, according to an example, the battery state estimation apparatus 120 may determine an open circuit potential (OCP) (hereinafter, referred to as a “first OCP”) (e.g., an OCP value corresponding to a surface concentration of each electrode to be described with reference to FIGS. 4 and 5) of each of electrodes of the battery 110 using the surface concentration of each electrode. That is, the battery state estimation apparatus 120 may determine the first OCP of a cathode of the battery 110, and determine the first OCP of an anode. The battery state estimation apparatus 120 may determine an open circuit voltage (OCV) (hereinafter, referred to as a “first OCV”) (e.g., an OCV1 to be described with reference to FIGS. 4 and 5) of the battery 110 using each determined first OCP. The battery state estimation apparatus 120 may compensate for the surface concentration of each electrode of the battery 110 based on an initial state variation d_SOC_0. The battery state estimation apparatus 120 may determine an OCP (hereinafter, referred to as a “second OCP”) (e.g., an OCP value corresponding to a moved (or compensated) surface concentration (X₁+dX) of each electrode to be described with reference to FIGS. 4 and 5) of each electrode using each compensated surface concentration. That is, the battery state estimation apparatus 120 may determine the second OCP of the cathode of the battery 110, and determine the second OCP of the anode. The battery state estimation apparatus 120 may determine an OCV (hereinafter, referred to as a “second OCV”) (e.g., an OCV2 to be described with reference to FIG. 4 or an OCV3 to be described with reference to FIG. 5) of the battery 110 using each determined second OCP. The battery state estimation apparatus 120 may determine the state variation d_SOC using the determined first OCV, the determined second OCV, the initial state variation d_SOC_0, and the determined voltage difference dV.

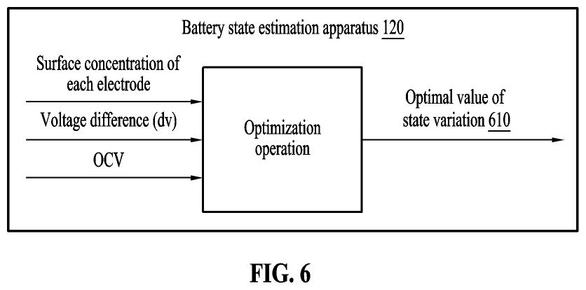

As will be described in greater detail below with reference to FIG. 6, according to an example, when the first OCV of the battery 110 is determined, the battery state estimation apparatus 120 may determine an optimal value of a state variation by performing an optimization operation of optimizing the state variation based on the determined voltage difference dV, the surface concentration of each electrode, and the determined first OCV.

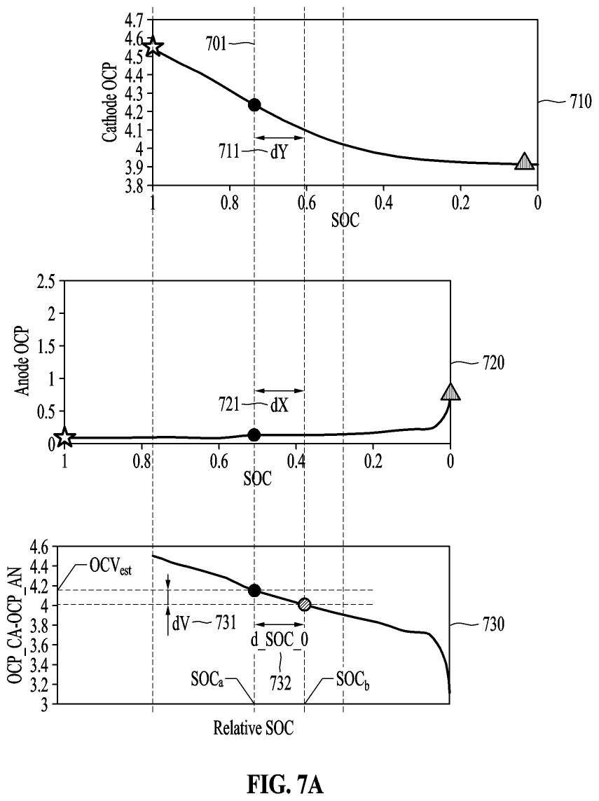

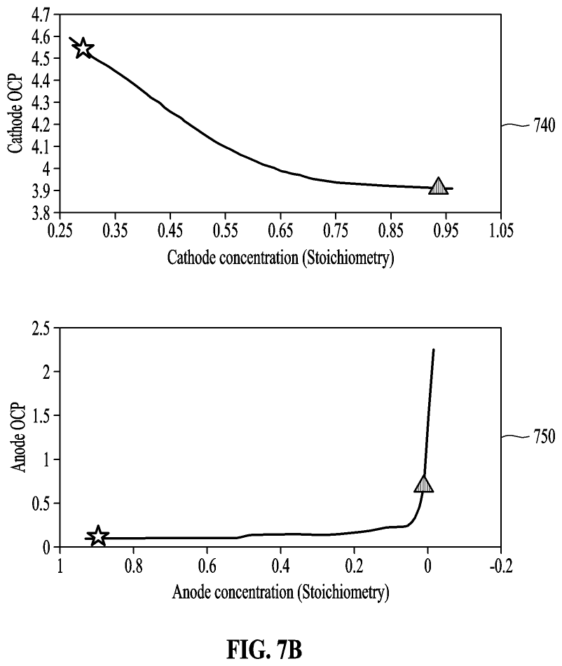

As will be described below in greater detail with reference to FIGS. 7A, 7B, and 8, in an example, the battery state estimation apparatus 120 may obtain a first ratio value corresponding to a cathode surface concentration of the battery 110 from a first table showing a relationship between a ratio dOCP/dY between a concentration variation dY and an OCP variation dOCP of the cathode among the electrodes of the battery 110 and a cathode concentration (e.g., a stoichiometric concentration). The battery state estimation apparatus 120 may obtain a second ratio value corresponding to an anode surface concentration from a second table showing a relationship between a ratio dOCP/dX between a concentration variation and an OCP variation of the anode of the battery 110 and an anode concentration (e.g., a stoichiometric concentration). The battery state estimation apparatus 120 may determine the state variation d_SOC using the determined voltage difference dV, the obtained first ratio value, the obtained second ratio value, and the initial state variation.

In operation 350, the battery state estimation apparatus (i.e, the battery state estimation apparatus 120) may update the battery model based on the determined state variation. In an example, the battery state estimation apparatus may update the battery model by compensating at least one (e.g., an ion concentration distribution in an active material particle and/or an ion concentration distribution in an electrode) of parameters of an electrochemical model based on the determined state variation.

In operation 360, the battery state estimation apparatus (i.e, the battery state estimation apparatus 120) may determine state information (e.g., a SOC, a SOH, etc.) of the battery (i.e., the battery 110) based on the updated battery model.

FIGS. 4 and 5 illustrate example illustrations of determining a state variation of a battery according to one or more embodiments.

Referring to FIGS. 4 and 5, in a non-limiting example, a graph 410 may correspond to a first OCP table and a graph 420 may correspond to a second OCP table. The first OCP table may, for example, correspond to an OCP table showing a relationship between the stoichiometric concentration and an OCP of the cathode of the battery 110. The graph 410 may show a curve (or a graph) of the OCP according to the stoichiometric concentration of the cathode of the battery 110. The second OCP table may, for example, correspond to an OCP table showing a relationship between the stoichiometric concentration and an OCP of the anode of the battery 110. The graph 420 may show a curve (or a graph) of the OCP according to the stoichiometric concentration of the anode of the battery 110.

The stoichiometric concentration may have, for example, an absolute value, while a SOC is a relative value and may have a designated position that may vary from 0% to 100% depending on an application.

Referring to FIG. 4, the battery state estimation apparatus 120 may determine the surface concentration of each electrode of the battery 110, the estimated voltage Vₑₛₜ of the battery 110, and a SOC (hereinafter, referred to as a “SOC1” in FIG. 4) of the battery 110 through the battery model.

The battery state estimation apparatus 120 may determine the voltage difference dV between the sensed voltage Vₛₑₙ of the battery 110 and the estimated voltage Vₑₛₜ of the battery 110. In an example, the estimated voltage Vₑₛₜ may be less than the sensed voltage Vₛₑₙ by 300 mV. The battery state estimation apparatus 120 may calculate the voltage difference dV as 300 mV according to “the sensed voltage Vₛₑₙ−the estimated voltage Vₑₛₜ”. A positive value (e.g., 300 mV) of the voltage difference dV may imply that the battery model determines the SOC1 to be less than an actual SOC of the battery 110 (e.g., a SOC of the battery 110 in a state in which various errors such as a sensor error and an error of the battery model are excluded) by the internal state (e.g., at least one parameter) of the battery model. The battery state estimation apparatus 120 may perform compensation (e.g., surface concentration compensation, compensation of an internal state of a battery model, etc.) such that a SOC to be determined by the battery model later matches the actual SOC of the battery 110 (or such that the battery model determines the SOC to be high later).

In an example, the cathode surface concentration of the battery 110 may be defined as Y1, and the anode surface concentration of the battery 110 may be defined as X1.

The battery state estimation apparatus 120 may obtain an OCP value (e.g., 3.95 V) corresponding to the cathode surface concentration Y1 from the first OCP table (or the graph 410). The battery state estimation apparatus 120 may obtain an OCP value (e.g., 0.17 V) corresponding to the anode surface concentration X1 in the second OCP table (or the graph 420).

The battery state estimation apparatus 120 may calculate a difference value (e.g., 3.78 V) between the OCP value (e.g., 3.95 V) and the OCP value (e.g., 0.17 V). The battery state estimation apparatus 120 may determine the calculated difference value (e.g., 3.78 V) as the OCV1 of the battery 110. The OCV1 may, for example, correspond to an OCV of the battery 110 in the SOC1.

The battery state estimation apparatus 120 may determine a concentration moved amount (or concentration variation) (e.g., dY 411 and dX 421 of FIG. 4) of each electrode. The cathode concentration moved amount (or concentration variation) dY 411 may indicate, for example, a degree that the cathode surface concentration Y1 is to be moved (or to be changed) in the graph 410. The anode concentration moved amount (or concentration variation) dX 421 may indicate, for example, a degree that the anode surface concentration X1 is to be moved (or to be changed) in the graph 420. The surface concentration of each electrode may be compensated by the concentration moved amount (or concentration variation) of each electrode, and the concentration moved amount may thus be expressed as a compensation value (or concentration compensation amount). The compensation value (or concentration compensation amount) of each electrode may indicate a degree the surface concentration of each electrode is to be compensated.

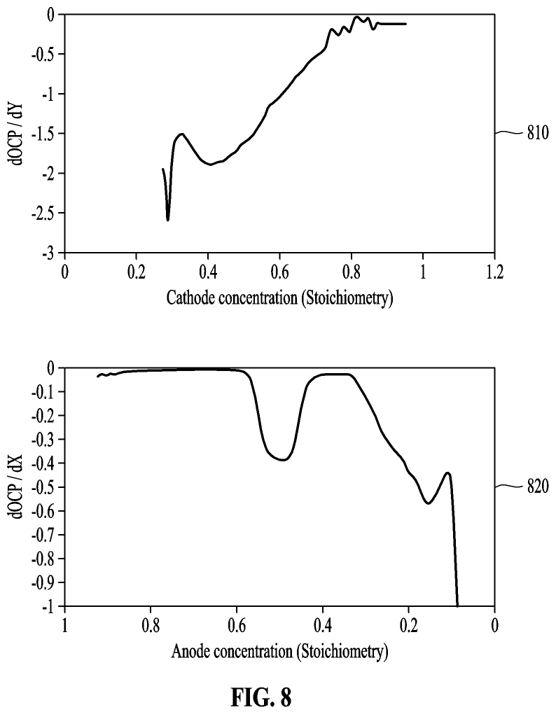

The battery state estimation apparatus 120 may determine the concentration moved amount (or compensation value) dY 411 for compensating the cathode surface concentration Y1 based on the initial state variation d_SOC_0. The battery state estimation apparatus 120 may determine the concentration moved amount (or compensation value) dX 421 for compensating the anode surface concentration X1 based on the initial state variation d_SOC_0. The initial state variation d_SOC_0 may have a fixed value, for example, but examples are not limited thereto. As will be described in greater detail below with reference to FIG. 9, the battery state estimation apparatus 120 may determine the initial state variation d_SOC_0 through the voltage difference dV and an OCV−SOC table (or an OCV−SOC graph).

In an example, the battery state estimation apparatus 120 may determine dY 411 (e.g., dY=d_SOC_0×d_SOC_CA) using the initial state variation d_SOC_0 and a predetermined value d_SOC_CA for the cathode of the battery 110. The battery state estimation apparatus 120 may determine dX 421 (e.g., dX=d_SOC_0×d_SOC_AN) using the initial state variation d_SOC_0 and a predetermined value d_SOC_AN for the anode of the battery 110. The voltage difference dV may be a positive number, d_SOC_CA may be a negative number, and d_SOC_AN may be a positive number, as will be described below. Accordingly, a relationship of “dY 411<0” may be satisfied, and a relationship of “dX 421>0” may be satisfied. The dY 411 may be a direction in which the cathode concentration (e.g., the cathode surface concentration or stoichiometric concentration) decreases, and the dX 421 may be a direction in which the anode concentration (e.g., the anode surface concentration or stoichiometric concentration) increases.

The predetermined value d_SOC_CA for the cathode may, in an example, represent a difference between a cathode concentration corresponding to SOC=100% and a cathode concentration corresponding to SOC=0%. For example, the cathode concentration corresponding to SOC=100% may be 0.3, and the cathode concentration corresponding to SOC=0% may be 0.9. In this case, the predetermined value d_SOC_CA for the cathode may be −0.6.

The predetermined value d_SOC_AN for the anode may, in an example, represent a difference between an anode concentration corresponding to SOC=100% and an anode concentration corresponding to SOC=0%. For example, the anode concentration corresponding to SOC=100% may be 0.9, and the anode concentration corresponding to SOC=0% may be 0.01. In this case, the predetermined value d_SOC_AN for the anode may be 0.89.

The battery state estimation apparatus 120 may compensate the cathode surface concentration Y1 through the dY 411. The compensated surface concentration Y1+dY may correspond to a position on the graph 410 where the surface concentration Y1 is moved by dY 411. The compensated surface concentration Y1+dY may be less than the surface concentration Y1. The battery state estimation apparatus 120 may obtain an OCP value (e.g., 4.1 V) corresponding to the compensated (or moved) cathode surface concentration Y1+dY in the first OCP table (or the graph 410). The battery state estimation apparatus 120 may compensate for the anode surface concentration X1 through the dX 421. The compensated surface concentration X1+dX may correspond to a position on the graph 420 where the surface concentration X1 is moved by dX 421. The compensated surface concentration X1+dX may be more than the surface concentration X1. The battery state estimation apparatus 120 may obtain an OCP value (e.g., 0.13 V) corresponding to the compensated (or moved) anode surface concentration X1+dX in the second OCP table (or the graph 420).

The battery state estimation apparatus 120 may calculate a difference value (e.g., 3.97 V) between the OCP value (e.g., 4.1 V) corresponding to the compensated cathode surface concentration and the OCP value (e.g., 0.13 V) corresponding to the compensated anode surface concentration. The battery state estimation apparatus 120 may determine the difference value (e.g., 3.97 V) as the OCV2 of the battery 110. The surface concentration of each electrode may be compensated based on the initial state variation d_SOC_0, and thus, the OCV2 of the battery 110 may correspond to an OCV obtained by compensating the OCV1 of the battery 110 based on the initial state variation d_SOC_0. The OCV2 may correspond to an OCV of the battery 110 in a SOC (e.g., SOC1+d_SOC_0) considering the initial state variation.

The battery state estimation apparatus 120 may determine the state variation (or a state error amount) d_SOC of the battery 110 using the initial state variation d_SOC_0, the OCV1 of the battery 110, the OCV2 of the battery 110, and the voltage difference dV. In an example, the battery state estimation apparatus 120 may determine the state variation d_SOC of the battery 110 by Equation 1 below.

$$d\_SOC \_ 0 : d\_SOC = OCV difference : dV \qquad Equation 1$$

In an example, an absolute value may be applied to an OCV difference and/or dV in Equation 1 above.

A ratio between d_SOC_0 and d_SOC may be equal to a ratio between the OCV difference (e.g., OCV2−OCV1=3.97 V−3.78 V=0.19 V) and the voltage difference dV. When d_SOC_0 is, for example, 3%, d_SOC may be “3%×0.3/0.19=4.73%”. In other words, the battery state estimation apparatus 120 may determine d_SOC to be 4.73% by applying d_SOC_0 to the ratio between the OCV difference and the voltage difference dV. As described above, the battery state estimation apparatus 120 may update the battery model based on the state variation d_SOC (e.g., 4.73%), and determine the state information (e.g., the SOC) of the battery 110 through the updated battery model. Therefore, the battery state estimation apparatus 120 may determine the state information with high accuracy.

Unlike the example shown in FIG. 4, in the example shown in FIG. 5, the estimated voltage Vₑₛₜ may be greater than the sensed voltage Vₛₑₙ. Hereinafter, an example in which the battery state estimation apparatus 120 determines the state variation when the estimated voltage Vₑₛₜ is greater than the sensed voltage Vₛₑₙ will be described with reference to FIG. 5.

Referring to FIG. 5, the battery state estimation apparatus 120 may determine a surface concentration of each electrode of the battery 110, the estimated voltage Vₑₛₜ of the battery 110, and the SOC (hereinafter, referred to as “SOC2” in FIG. 5) of the battery 110 through the battery model.

The battery state estimation apparatus 120 may determine the voltage difference dV between the sensed voltage Vₛₑₙ of the battery 110 and the estimated voltage Vₑₛₜ of the battery 110. In an example, the estimated voltage Vₑₛₜ may be greater than the sensed voltage Vₛₑₙ by 200 mV. The battery state estimation apparatus 120 may calculate the voltage difference dV as −200 mV according to “the sensed voltage Vₛₑₙ−the estimated voltage Vₑₛₜ”. A negative value (e.g., −200 mV) of the voltage difference dV may imply that the battery model determines the SOC2 to be greater than the actual SOC of the battery 110 by the internal state of the battery model. The battery state estimation apparatus 120 may perform compensation (e.g., surface concentration compensation, compensation of an internal state of a battery model, etc.) such that a SOC to be determined by the battery model later is close to the actual SOC of the battery 110 (or such that the battery model determines the SOC to be low later).

As illustrated in FIG. 5, in an example, the cathode surface concentration of the battery 110 may be defined as Y1, and the anode surface concentration of the battery 110 may be defined as X1.

The battery state estimation apparatus 120 may obtain an OCP value (e.g., 3.95 V) corresponding to the cathode surface concentration Y1 from the first OCP table (or the graph 410). The battery state estimation apparatus 120 may obtain an OCP value (e.g., 0.17 V) corresponding to the anode surface concentration X1 from the second OCP table (or the graph 420).

The battery state estimation apparatus 120 may calculate a difference value (e.g., 3.78 V) between the OCP value (e.g., 3.95 V) and the OCP value (e.g., 0.17 V). The battery state estimation apparatus 120 may determine the calculated difference value (e.g., 3.78 V) as OCV1 of the battery 110.

The battery state estimation apparatus 120 may determine a compensation value (or concentration moved amount) dY 511 for compensating the cathode surface concentration Y1 based on the initial state variation d_SOC_0. In an example, when the voltage difference dV is a negative number, the battery state estimation apparatus 120 may change (or convert) the sign of the initial state variation d_SOC_0. For example, d_SOC_0 may be 3%. As described above with reference to FIG. 4, when the voltage difference dV is a positive number, the battery state estimation apparatus 120 may use d_SOC_0 without the sign change (or sign conversion). When the voltage difference dV is a negative number, the battery state estimation apparatus 120 may change (or convert) d_SOC_0 to −3% through the sign change (or sign conversion). The battery state estimation apparatus 120 may determine a compensation value (or concentration moved amount) dX 521 for compensating the anode surface concentration X1 based on the changed initial state variation−d_SOC_0 (e.g., −3%).

In an example, the battery state estimation apparatus 120 may determine dY 511 (e.g., dY=−d_SOC_0×d_SOC_CA) using the changed initial state variation−d_SOC_0 and the predetermined value d_SOC_CA for the cathode of the battery 110. Here, −d_SOC_0 may be a negative number, d_SOC_CA may be, as described above, a negative number, and thus dY 511 may be a positive number. The battery state estimation apparatus 120 may determine dX 521 (e.g., dX=−d_SOC_0×d_SOC_AN) using the initial state variation−d_SOC_0 and the predetermined value d_SOC_AN for the anode of the battery 110. Here, −d_SOC_0 may be, as described above, a negative number, d_SOC_AN may be, as described above, a positive number, and thus dX 521 may be a negative number. Since the voltage difference dV is a negative number, the dY 511 may be a direction on graph 410 in which the cathode concentration (e.g., the cathode surface concentration or stoichiometric concentration) increases, and the dX 521 may be a direction in which the anode concentration (e.g., the anode surface concentration or stoichiometric concentration) decreases.

The battery state estimation apparatus 120 may compensate the cathode surface concentration Y1 through the dY 511. The compensated cathode surface concentration Y1+dY may be greater than the cathode surface concentration Y1. The battery state estimation apparatus 120 may obtain an OCP value (e.g., 3.91 V) corresponding to the compensated cathode surface concentration Y1+dY in the first OCP table (or the graph 410). The battery state estimation apparatus 120 may compensate the anode surface concentration X1 through the dX 521. The dX 521 may be a negative number, and thus the compensated anode surface concentration X1+dX may be less than the anode surface concentration X1. The battery state estimation apparatus 120 may obtain an OCP value (e.g., 0.21 V) corresponding to the compensated anode surface concentration X1+dX in the second OCP table (or the graph 420).

The battery state estimation apparatus 120 may calculate a difference value (e.g., 3.7 V) between the OCP value (e.g., 3.91 V) corresponding to the compensated cathode surface concentration and the OCP value (e.g., 0.21 V) corresponding to the compensated anode surface concentration. The battery state estimation apparatus 120 may determine the calculated difference value (e.g., 3.7 V) as the OCV3 of the battery 110.

The battery state estimation apparatus 120 may determine the state variation (or the state error amount) d_SOC of the battery 110 using the changed initial state variation−d_SOC_0 (e.g., −3%), the OCV1 of the battery 110 (e.g., 3.78 V), the OCV3 of the battery 110 (e.g., 3.7 V), and the voltage difference dV (e.g., −0.2 V). For example, the battery state estimation apparatus 120 may determine the state variation d_SOC of the battery 110 by Equation 1 above. According to Equation 1, a ratio between d_SOC_0 and d_SOC may be equal to a ratio between the OCV difference (e.g., OCV3−OCV1=3.7 V−3.78 V=−0.08 V) and the voltage difference dV. When −d_SOC_0 is, for example, −3%, d_SOC may be “−3%×(−0.2)/(−0.08)=−7.5%”. In other words, in the example shown in FIG. 5, the battery state estimation apparatus 120 may determine d_SOC to be −7.5%. As described above, the battery state estimation apparatus 120 may update the battery model based on the state variation d_SOC (e.g., −7.5%), and determine the state information (e.g., the SOC) of the battery 110 through the updated battery model. Therefore, the battery state estimation apparatus 120 may determine the state information with high accuracy.

FIG. 6 illustrates an example method of determining a state variation of a battery according to one or more embodiments.

Referring to FIG. 6, in a non-limiting example, the battery state estimation apparatus 120 may determine the first OCV (e.g., the OCV1 described above with reference to FIGS. 4 and 5) of the battery 110. The battery state estimation apparatus 120 may determine an optimal value 610 of the state variation d_SOC by performing an optimization operation of optimizing the state variation d_SOC based on the determined voltage difference dV, the surface concentration of each electrode of the battery 110, and the determined first OCV. In the example described with reference to FIG. 6, the determined voltage difference dV may be a positive number.

In an example, the battery state estimation apparatus 120 may determine the optimal value 610 of the state variation d_SOC by performing the optimization operation by Equation 2 below.

$$dV = OCV ( SOC + d\_SOC ) - OCV ( SOC ) \qquad Equation 2$$

$$OCV ( SOC ) = OCP\_CA ( Y ) - OPC\_AN ( X )$$

$$OCV ( SOC + d\_SOC ) = OCP\_CA ( Y + dY ) - OCP\_AN ( X + dX )$$

$$dY = {d}_{-} {SOC}_{-} 0 \times {d}_{-} {SOC}_{-} CA$$

$$dX = {d}_{-} {SOC}_{-} 0 \times {d}_{-} {SOC}_{-} A N$$

In Equation 2, OCV(SOC) may denote an OCV in a SOC (e.g., the SOC1 described above) determined by the battery model. OCV(SOC+d_SOC) may denote an OCV in SOC+d_SOC. In other words, OCV(SOC+d_SOC) may denote an OCV considering d_SOC. In equation 2, OCP_CA(⋅) may denote the first OCP table (or the graph 410), and OCP_AN(⋅) may denote the second OCP table (or the graph 420). In equation 2, OCP_CA(Y) may denote a cathode OCP corresponding to a cathode surface concentration Y of the battery 110, and OCP_AN(X) may denote an anode OCP corresponding to an anode surface concentration X of the battery 110. The cathode surface concentration Y and the anode surface concentration X may be determined by the battery model. As described above, d_SOC_0, d_SOC_CA, and d_SOC_AN may denote the initial state variation, the predetermined value for the cathode of the battery 110, and the predetermined value for the anode of the battery 110, respectively.

In an example, the battery state estimation apparatus 120 may determine the cathode surface concentration and the anode surface concentration of the battery 110 as Y1 and X1, respectively, through the battery model, and determine a SOC of the battery 110 as the SOC1 through the battery model. The battery state estimation apparatus 120 may determine the voltage difference dV as 300 mV. The battery state estimation apparatus 120 may determine OCP_CA(Y1) as 3.95 V through the first OCP table, and determine OCP_AN(X1) as 0.17 V through the second OCP table. The battery state estimation apparatus 120 may determine OCV(SOC1) as 3.78 V.

Based on “dV=OCV(SOC+d_SOC)−OCV(SOC)” of Equation 2, the battery state estimation apparatus 120 may calculate a correction value (e.g., initial state variation d_SOC_0) so that a difference between OCV(SOC) and OCV(SOC+d_SOC) to be equal to the voltage difference dV (e.g., 0.3 V). That is, the values dX and dY may be adjusted by the correction value based on the initial state variation d_SOC_0. The initial state variation d_SOC_0 may be, for example, 0.03 (or 3%), d_SOC_CA may be, for example, −0.6, and d_SOC_AN may be, for example, 0.89. Accordingly, with these example values, the battery state estimation apparatus 120 may determine, through the calculating of the correction value that dY is to be −0.018 and dX is to be 0.0267.

That is, in an example, the battery state estimation apparatus 120 may determine the optimal value 610 of the state variation d_SOC by performing the optimization operation on dV=OCV(SOC1+d_SOC)−OCV(SOC1) and OCV(SOC1+d_SOC)=OCP_CA(Y1+dY)−OCP_AN(X1+dX). The optimization operation may include, for example, a global optimization method, a gradient descent method, or the like.

When the optimal value 610 is determined, the battery state estimation apparatus 120 may update the battery model based on the optimal value 610, and determine the state information (e.g., the SOC) of the battery 110 through the updated battery model. At this time, in a case of the determined state information, the voltage difference dV described above may be minimized. Therefore, the battery state estimation apparatus 120 may determine the state information with high accuracy.

FIGS. 7A, 7B, and 8 illustrate example illustrations of determining a state variation of a battery according to one or more embodiments.

Referring to FIG. 7A, in a non-limiting example, a graph 710 of a cathode OCP OCP_CA according to a SOC and a graph 720 of an anode OCP OCP_AN according to a SOC are illustrated. The graph 710 of the cathode OCP according to the SOC may be, in an example, derived from a graph 740 of an OCP according to a cathode concentration (e.g., a cathode stoichiometric concentration) of the battery 110 shown in FIG. 7B. The graph 710 may be derived from the graph 740 as the cathode concentration of the battery 110 is converted into the SOC according to a determined conversion relationship. The graph 720 of the anode OCP according to the SOC may be, in an example, derived from a graph 750 of an OCP according to an anode concentration (e.g., an anode stoichiometric concentration) of the battery 110 shown in FIG. 7B. The graph 720 may be derived from the graph 750 as the anode concentration of the battery 110 is converted into the SOC according to a determined conversion relationship.

In an example, the deriving of the graph 710 from the graph 740 and the deriving of the graph 720 from the graph 750 may be performed by the battery state estimation apparatus 120. However, examples are not limited thereto, and the battery state estimation apparatus 120 may store the graph 710 (or a table corresponding to the graph 710) and the graph 720 (or a table corresponding to the graph 720) in advance.

The battery state estimation apparatus 120 may determine a cathode surface concentration of the battery 110 as, for example, 0.42 using the battery model, determine an anode surface concentration of the battery 110 as, for example, 0.5, and estimate an OCV and a voltage of the battery 110.

The battery state estimation apparatus 120 may determine the voltage difference dV between a sensed voltage of the battery 110 and an estimated voltage of the battery 110 as, for example, −0.15.

The battery state estimation apparatus 120 may obtain a SOC (e.g., 0.75) corresponding to the cathode surface concentration (e.g., 0.42) through the determined conversion relationship. The battery state estimation apparatus 120 may obtain a SOC (e.g., 0.5) corresponding to the anode surface concentration (e.g., 0.5) through the determined conversion relationship.

In an example, the battery state estimation apparatus 120 may move the graph 710 and/or the graph 720 such that the SOC (e.g., 0.75) corresponding to the cathode surface concentration (e.g., 0.42) and the SOC (e.g., 0.5) corresponding to the anode surface concentration (e.g., 0.5) are aligned. Accordingly, as in the example shown in FIG. 7A, the SOC (e.g., 0.75) corresponding to the cathode surface concentration (e.g., 0.42) and the SOC (e.g., 0.5) corresponding to the anode surface concentration (e.g., 0.5) may be aligned on a line 701 by the movement of the graphs 710 and/or 720. For convenience, in the example shown in FIG. 7A, it is illustrated that the graph 710 is moved (i.e., a moved graph 710).

The battery state estimation apparatus 120 may obtain a graph 730 by subtracting the graph 720 from the moved graph 710. The x-axis of the graph 730 may indicate a relative SOC (e.g., a result obtained by subtracting the SOC of the x-axis of the graph 720 from the SOC of the x-axis of the moved graph 710). On the x-axis of the graph 730, SOCₐ may be, for example, 0.25. The y-axis of the graph 730 may indicate a difference between the cathode OCP OCP_CA and the anode OCP OCP_AN. The difference between the cathode OCP OCP_CA and the anode OCP OCP_AN may represent, for example, an OCV.

The battery state estimation apparatus 120 may apply a voltage difference dV 731 (e.g., −0.15) to an estimated OCV (e.g., OCVₑₛₜ of FIG. 7A). The battery state estimation apparatus 120 may determine SOC_{b} corresponding to “OCVₑₛₜ+dV 731” in the graph 730. The battery state estimation apparatus 120 may determine the difference between the SOC_{b} and the SOCₐ (e.g., 0.75−0.5=0.25) corresponding to the estimated OCV OCVₑₛₜ as an initial state variation d_SOC_0. In the illustration of FIG. 7A, in an example, the battery state estimation apparatus 120 may determine the initial state variation d_SOC_0 to be −13%.

A predetermined value d_SOC_CA for the cathode of the battery 110 may be, for example, −0.6, and a predetermined value d_SOC_AN for the anode of the battery 110 may be, for example, 0.89.

According to the above example values, the battery state estimation apparatus 120 may determine dY 711 of FIG. 7A as 0.078 according to “dY=d_SOC_0×d_SOC_CA”, and determine dX 721 of FIG. 7A as −0.1157 according to “dX=d_SOC_0×d_SOC_AN”.

The battery state estimation apparatus 120 may determine a ratio value (hereinafter, referred to as a “first ratio value”) (e.g., −1.8) corresponding to the cathode surface concentration (e.g., 0.42) of the battery 110 using a graph 810 of FIG. 8. Referring to FIG. 8, in a non-limiting example, graph 810 may illustrate a relationship between a ratio dOCP/dY between a cathode concentration variation dY and a cathode OCP variation dOCP of the battery 110 and a cathode concentration (e.g., a cathode stoichiometric concentration). The graph 810 may be determined, for example, based on the first OCP table.

The battery state estimation apparatus 120 may determine a ratio value (hereinafter, referred to as a “second ratio value”) (e.g., −0.4) corresponding to the anode surface concentration (e.g., 0.5) of the battery 110 using a graph 820 of FIG. 8. The graph 820 may show, in an example, a relationship between a ratio dOCP/dX between an anode concentration variation dX and an anode OCP variation dOCP of the battery 110 and an anode concentration (e.g., an anode stoichiometric concentration). The graph 820 may be determined, for example, based on the second OCP table.

In an example, referring back to FIG. 7A, the battery state estimation apparatus 120 may determine a cathode OCP variation value dOCP_CA based on the first ratio value and the dY 711, and determine an anode OCP variation value dOCP_AN based on the second ratio value and the dX 721. The dOCP may be determined when the dY is multiplied by the dOCP/dY. The battery state estimation apparatus 120 may determine the cathode OCP variation value dOCP_CA (e.g., −0.1404) by multiplying the dY 711 (e.g., 0.078) by the first ratio value (e.g., −1.8). Similarly, the battery state estimation apparatus 120 may determine the anode OCP variation value dOCP_AN (e.g., 0.04628) by multiplying the dX 721 (e.g., −0.1157) by the second ratio value (e.g., −0.4).

The battery state estimation apparatus 120 may determine an OCV difference doCV of the battery 110 based on the cathode OCP variation value dOCP_CA and the anode OCP variation value dOCP_AN. For example, “dOCV=dOCP_CA+dOCP_AN”. The battery state estimation apparatus 120 may determine the OCV difference dOCV (e.g., −0.09412) of the battery 110 according to “dOCV=dOCP_CA+dOCP_AN”.

The battery state estimation apparatus 120 may determine a state variation d_SOC using the initial state variation d_SOC_0 (e.g., −0.13% or −13%), the OCV difference dOCV (e.g., about −0.094), and the voltage difference dV (e.g., −0.15). For example, the battery state estimation apparatus 120 may determine the state variation d_SOC (e.g., −20.7%) by Equation 1 above.

In an example, when one of the first ratio value or the second ratio value is greater than the other one by a predetermined level, the battery state estimation apparatus 120 may use the greater ratio value. For example, the battery state estimation apparatus 120 may determine the first ratio value to be −1.8, and determine the second ratio value to be −0.4. In this case, the battery state estimation apparatus 120 may determine that the first ratio value (e.g., 1.8) is greater than the second ratio value (e.g., 0.4) by a predetermined level. Accordingly, the battery state estimation apparatus 120 may use the first ratio value instead of the second ratio value because the first ratio value is greater than the second ratio value. The battery state estimation apparatus 120 may determine the dY 711 of FIG. 7A to be 0.078 according to “dY=d_SOC_0×d_SOC_CA”. The battery state estimation apparatus 120 may determine the cathode OCP variation value dOCP_CA (e.g., −0.1404) by multiplying the dY 711 (e.g., 0.078) by the first ratio value (e.g., −1.8). The battery state estimation apparatus 120 may determine the cathode OCP variation value dOCP_CA as the OCV difference dOCV. When the first ratio value is greater than the second ratio value by a predetermined level or higher, dOCV=dOCP_CA=−0.1404. The battery state estimation apparatus 120 may determine the state variation d_SOC to be −13.9% by Equation 1 above.

FIG. 9 illustrates an example illustration of determining an initial state variation of a battery state according to one or more embodiments.

Referring to FIG. 9, in a non-limiting example, a graph 910 between a SOC and an OCV is illustrated.

When a voltage difference dV is determined, the battery state estimation apparatus 120 may determine an initial state variation d_SOC_0 using the determined voltage difference dV and the graph 910 (or a table between the SOC and the OCV).

In an example, the battery state estimation apparatus 120 may determine an estimated voltage Vₑₛₜ of a battery and a SOC (hereinafter, referred to as a “SOC1” in FIG. 9) of the battery 110 through a battery model. The battery state estimation apparatus 120 may determine the voltage difference dV between a sensed voltage Vₛₑₙ and the estimated voltage Vₑₛₜ of the battery 110. The battery state estimation apparatus 120 may obtain an OCV1 corresponding to the SOC1 in the graph 910. The battery state estimation apparatus 120 may obtain a SOC2 corresponding to a result (OCV1+dV) (OCV2 in FIG. 9) of adding the obtained OCV1 and the determined voltage difference dV. The battery state estimation apparatus 120 may determine a difference between the SOC1 and the SOC2 as the initial state variation d_SOC_0.

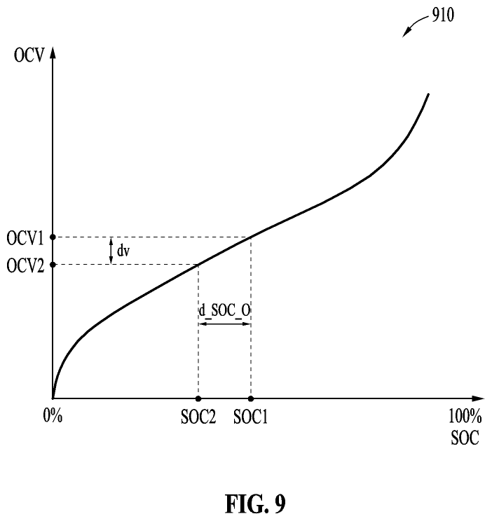

FIG. 10 illustrates an example battery state estimation apparatus according to one or more embodiments.

Referring to FIG. 10, in a non-limiting example, the battery state estimation apparatus 120 may include a processor 1010, a voltage sensor 1020, and a memory 1030.

The memory 1030 may include computer-readable instructions. The processor 1010 may be configured to execute computer-readable instructions, such as those stored in the memory 1030, and through execution of the computer-readable instructions, the processor 1010 is configured to perform one or more, or any combination, of the operations and/or methods described herein. The memory 1030 may be a volatile or nonvolatile memory. In an example, the memory 1030 may store a battery model (e.g., an electrochemical model).

The processor 1010 may include various processing circuitry, including at least one processor. The processor 1010 may be configured to execute instructions (or programs or applications) to cause or configure the processor 1010 to control the battery state estimation apparatus 120 to perform one or more or all operations and/or methods involving the battery state estimation, and may include any one or a combination of two or more of, for example, a central processing unit (CPU), a graphic processing unit (GPU), a neural processing unit (NPU) and tensor processing units (TPUs), but is not limited to the above-described examples. Processors, individually and/or collectively may perform one or more or all operations and/or methods involving the battery state estimation 120.

The processor 1010 may determine an estimated voltage of the battery 110 and a surface concentration of each of electrodes of the battery 110 through the battery model.

The processor 1010 may obtain a sensed voltage of the battery 110 using the voltage sensor 1020.

The processor 1010 may determine a voltage difference dV between the obtained sensed voltage and the determined estimated voltage.

The processor 1010 may determine a state variation d_SOC of the battery based on the determined voltage difference and each determined surface concentration.

In an example, the processor 1010 may determine a first OCP of each of the electrodes of the battery 110 (e.g., an anode and cathode) using each determined surface concentration. For example, the processor 1010 may determine the first OCP of each of the electrodes of the battery 110 using each OCP table showing a relationship between a stoichiometric concentration and an OCP of each of the electrodes of the battery 110 and each determined surface concentration.

The processor 1010 may determine a first OCV (e.g., the OCV1 described above) of the battery 110 using each determined first OCP. The processor 1010 may compensate for each surface concentration based on an initial state variation d_SOC_0. In an example, the processor 1010 may determine each compensation value for compensating each surface concentration using a predetermined value for each of the electrodes of the battery 110 and the initial state variation d_SOC_0, and compensate each surface concentration based on each determined compensation value.

The processor 1010 may determine a second OCP of each of the electrodes of the battery 110 using each compensated surface concentration. In an example, the processor 1010 may determine the second OCP of each of the electrodes of the battery 110 using each OCP table and each compensated surface concentration. The processor 1010 may determine a second OCV (e.g., the OCV2 or the OCV3 described above) of the battery 110 using each determined second OCP.

The processor 1010 may determine the state variation d_SOC using the determined first OCV, the determined second OCV, the initial state variation, and the determined voltage difference. In an example, the processor 1010 may determine a difference value between the determined second OCV and the determined first OCV, and determine the state variation by applying a ratio between the determined difference value and the determined voltage difference dV to the initial state variation.

In an example, the processor 1010 may determine an optimal value of the state variation by performing an optimization operation of optimizing the state variation d_SOC based on the determined voltage difference dV, each determined surface concentration, and the determined OCV (e.g., the first OCV). In this case, the processor 1010 may perform the optimization operation by setting such that a voltage difference between the determined OCV and an OCV (e.g., OCV (SOC+d_SOC)) considering the state variation is the same as the determined voltage difference dV.

In an example, the processor 1010 may, from a first table (or the graph 810) showing a relationship between a ratio between a concentration variation and an OCP variation of a first electrode (e.g., a cathode) of the battery 110, and a concentration of the first electrode, obtain a first ratio value corresponding to the surface concentration of the first electrode. The first table may be, for example, determined from the graph 810. The processor 1010 may, from a second table (or the graph 820) showing a relationship between a ratio between a concentration variation and an OCP variation of a second electrode (e.g., an anode) of the battery 110, and a concentration of the second electrode, obtain a second ratio value corresponding to the surface concentration of the second electrode. The second table may be, for example, determined from the graph 820.

The processor 1010 may determine the state variation using the determined voltage difference dV, the obtained first ratio value, the obtained second ratio value, and the initial state variation. In an example, the processor 1010 may determine a first compensation value (e.g., the dY 711 of FIG. 7A) for compensating the surface concentration of the first electrode by applying the initial state variation (e.g., the initial state variation 732 of FIG. 7A) to a predetermined value (e.g., d_SOC_CA) for the first electrode. The processor 1010 may determine a first OCP variation value (e.g., the dOCP_CA described above) of the first electrode using the determined first compensation value and the obtained first ratio value. The processor 1010 may determine a second compensation value (e.g., the dX 721 of FIG. 7A) for compensating the surface concentration of the second electrode by applying the initial state variation (e.g., the initial state variation 732 of FIG. 7A) to a predetermined value (e.g., d_SOC_AN) for the second electrode. The processor 1010 may determine a second OCP variation value (e.g., the dOCP_AN described above) of the second electrode using the determined second compensation value and the obtained second ratio value. The processor 1010 may calculate a sum of the determined first OCP variation value and the determined second OCP variation value. In this case, the calculated sum may correspond to the dOCV as described above. The processor 1010 may determine the state variation d_SOC by applying a ratio (e.g., dV/dOCV) between the determined voltage difference and the calculated sum to the initial state variation (e.g., the initial state variation 732 of FIG. 7A). The example of determining the state variation using the determined voltage difference dV, the obtained first ratio value, the obtained second ratio value, and the initial state variation has been described above in greater detail with reference to FIGS. 7A, 7B, and 8, and therefore the detailed description will be omitted.

The processor 1010 may update the battery model based on the determined state variation. In an example, the processor 1010 may update the battery model by compensating at least one of parameters (e.g., an ion concentration distribution in an active material particle and/or an ion concentration distribution in an electrode) of an electrochemical model based on the determined state variation.

The processor 1010 may determine state information (e.g., a SOC or the like) of the battery 110 based on the updated battery model.

The examples described above with reference to FIGS. 1 to 9 may be applied to the battery state estimation apparatus 120 of FIG. 10.

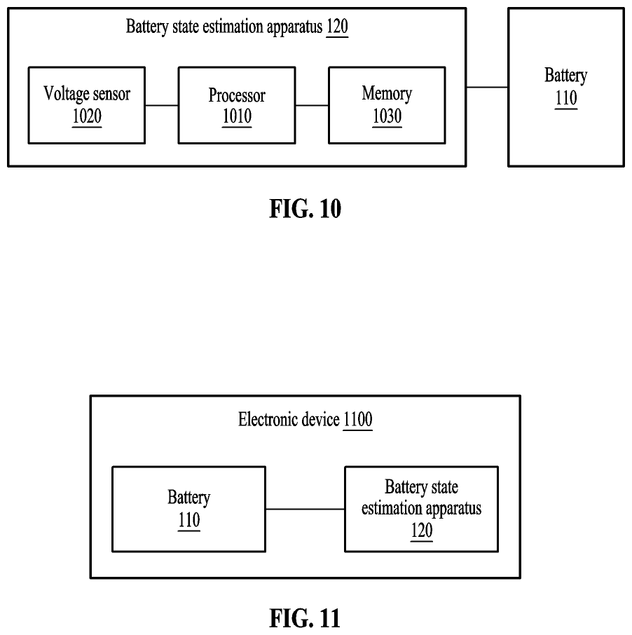

FIG. 11 illustrates an example electronic device including a battery state estimation apparatus according to one or more embodiments.

Referring to FIG. 11, in a non-limiting example, an electronic device 1100 may include the battery 110 and the battery state estimation apparatus 120.

In an example, the electronic device 1100 may be applied to a vehicle (e.g., an electric vehicle, etc.), a mobile device (e.g., a smartphone, a tablet personal computer (PC), etc.), and the like.

The electronic device 1100 may determine an estimated voltage of the battery 110 and a surface concentration of each of electrodes of the battery 110 through the battery model. The electronic device 1100 may obtain a sensed voltage of the battery 110 using a voltage sensor. The electronic device 1100 may determine a voltage difference between the obtained sensed voltage and the determined estimated voltage. The electronic device 1100 may determine a state variation of the battery 110 based on the determined voltage difference and each determined surface concentration. The electronic device 1100 may update the battery model based on the determined state variation. The electronic device 1100 may determine state information of the battery 110 based on the updated battery model. The electronic device 1100 may display the determined state information on a display.

The examples described above with reference to FIGS. 1 to 10 may be applied to the electronic device 1100 of FIG. 11.

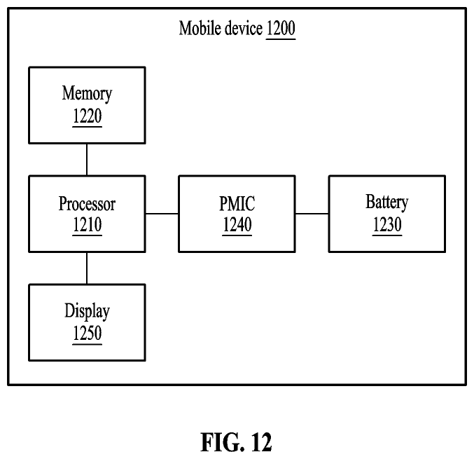

FIG. 12 illustrates an example mobile device according to one or more embodiments.

Referring to FIG. 12, in a non-limiting example, a mobile device 1200 may include a processor 1210, a memory 1220, a battery 1230, a power management integrated circuit (PMIC) 1240, and a display 1250.

The processor 1210 may include various processing circuitry, including at least one processor.

The memory 1220 may include computer-readable instructions. The processor 1210 may be configured to execute computer-readable instructions, such as those stored in the memory 1220, and execution of the computer-readable instructions causes the processor 1210 to perform one or more, or any combination, of the operations and/or methods described herein. The memory 1220 may be a volatile or nonvolatile memory. The memory 1220 may store a battery model.

In an example, the PMIC 1240 may charge the battery 1230 with power received from an external device (e.g., a travel adapter or a wireless charger) of the mobile device 1200. The PMIC 1240 may supply power stored in the battery 1230 to components (e.g., the processor 1210 and the like) of the mobile device 1200.

The PMIC 1240 may obtain a sensed voltage by sensing a voltage of the battery 1230 through a voltage sensor, and transfer the obtained sensed voltage to the processor 1210. In an example, a voltage sensor may be positioned near the battery 1230, and the voltage sensor may sense the voltage of the battery 1230 and transfer the obtained sensed voltage to the processor 1210.

The processor 1210 may perform at least some or all of the operations of the battery state estimation apparatus 120 described above. The processor 1210 may determine an estimated voltage of the battery 1230 and a surface concentration of each of electrodes of the battery 1230 through the battery model. The processor 1210 may determine a voltage difference between the obtained sensed voltage and the determined estimated voltage. The processor 1210 may determine a state variation of the battery 1230 based on the determined voltage difference and each determined surface concentration. The processor 1210 may update a battery model based on the determined state variation. The processor 1210 may determine state information of the battery 1230 based on the updated battery model. The processor 1210 may control the display 1250 such that the determined state information is displayed on the display 1250.

The examples described above with reference to FIGS. 1 to 11 may be applied to the mobile device 1200 of FIG. 12.

The processors, memories, battery, battery state estimating apparatuses, electronic apparatuses, battery system 100, battery 110, battery state estimation apparatus 120, processor 1010, voltage sensor 1020, memory 1030, electronic device 1100, mobile device 1200, processor 1210, memory 1220, battery 1230, PMIC 1240, and display 1250 described herein and disclosed herein described with respect to FIGS. 1-12 are implemented by or representative of hardware components. As described above, or in addition to the descriptions above, examples of hardware components that may be used to perform the operations described in this application where appropriate include controllers, sensors, generators, drivers, memories, comparators, arithmetic logic units, adders, subtractors, multipliers, dividers, integrators, and any other electronic components configured to perform the operations described in this application. In other examples, one or more of the hardware components that perform the operations described in this application are implemented by computing hardware, for example, by one or more processors or computers. A processor or computer may be implemented by one or more processing elements, such as an array of logic gates, a controller and an arithmetic logic unit, a digital signal processor, a microcomputer, a programmable logic controller, a field-programmable gate array, a programmable logic array, a microprocessor, or any other device or combination of devices that is configured to respond to and execute instructions in a defined manner to achieve a desired result. In one example, a processor or computer includes, or is connected to, one or more memories storing instructions or software that are executed by the processor or computer. Hardware components implemented by a processor or computer may execute instructions or software, such as an operating system (OS) and one or more software applications that run on the OS, to perform the operations described in this application. The hardware components may also access, manipulate, process, create, and store data in response to execution of the instructions or software. For simplicity, the singular term “processor” or “computer” may be used in the description of the examples described in this application, but in other examples multiple processors or computers may be used, or a processor or computer may include multiple processing elements, or multiple types of processing elements, or both. For example, a single hardware component or two or more hardware components may be implemented by a single processor, or two or more processors, or a processor and a controller. One or more hardware components may be implemented by one or more processors, or a processor and a controller, and one or more other hardware components may be implemented by one or more other processors, or another processor and another controller. One or more processors, or a processor and a controller, may implement a single hardware component, or two or more hardware components. As described above, or in addition to the descriptions above, example hardware components may have any one or more of different processing configurations, examples of which include a single processor, independent processors, parallel processors, single-instruction single-data (SISD) multiprocessing, single-instruction multiple-data (SIMD) multiprocessing, multiple-instruction single-data (MISD) multiprocessing, and multiple-instruction multiple-data (MIMD) multiprocessing.

The methods illustrated in FIGS. 1-12 that perform the operations described in this application are performed by computing hardware, for example, by one or more processors or computers, implemented as described above implementing instructions or software to perform the operations described in this application that are performed by the methods. For example, a single operation or two or more operations may be performed by a single processor, or two or more processors, or a processor and a controller. One or more operations may be performed by one or more processors, or a processor and a controller, and one or more other operations may be performed by one or more other processors, or another processor and another controller. One or more processors, or a processor and a controller, may perform a single operation, or two or more operations.

Instructions or software to control computing hardware, for example, one or more processors or computers, to implement the hardware components and perform the methods as described above may be written as computer programs, code segments, instructions or any combination thereof, for individually or collectively instructing or configuring the one or more processors or computers to operate as a machine or special-purpose computer to perform the operations that are performed by the hardware components and the methods as described above. In one example, the instructions or software include machine code that is directly executed by the one or more processors or computers, such as machine code produced by a compiler. In another example, the instructions or software includes higher-level code that is executed by the one or more processors or computer using an interpreter. The instructions or software may be written using any programming language based on the block diagrams and the flow charts illustrated in the drawings and the corresponding descriptions herein, which disclose algorithms for performing the operations that are performed by the hardware components and the methods as described above.

The instructions or software to control computing hardware, for example, one or more processors or computers, to implement the hardware components and perform the methods as described above, and any associated data, data files, and data structures, may be recorded, stored, or fixed in or on one or more non-transitory computer-readable storage media, and thus, not a signal per se. As described above, or in addition to the descriptions above, examples of a non-transitory computer-readable storage medium include one or more of any of read-only memory (ROM), random-access programmable read only memory (PROM), electrically erasable programmable read-only memory (EEPROM), random-access memory (RAM), dynamic random access memory (DRAM), static random access memory (SRAM), flash memory, non-volatile memory, CD-ROMs, CD-Rs, CD+Rs, CD-RWs, CD+RW, DVD-ROMs, DVD-Rs, DVD+Rs, DVD-RWs, DVD+RWs, DVD-RAMs, BD-ROMs, BD-Rs, BD-R LTHs, BD-REs, blue-ray or optical disk storage, hard disk drive (HDD), solid state drive (SSD), flash memory, a card type memory such as multimedia card micro or a card (for example, secure digital (SD) or extreme digital (XD)), magnetic tapes, floppy disks, magneto-optical data storage devices, optical data storage devices, hard disks, solid-state disks, and/or any other device that is configured to store the instructions or software and any associated data, data files, and data structures in a non-transitory manner and provide the instructions or software and any associated data, data files, and data structures to one or more processors or computers so that the one or more processors or computers can execute the instructions. In one example, the instructions or software and any associated data, data files, and data structures are distributed over network-coupled computer systems so that the instructions and software and any associated data, data files, and data structures are stored, accessed, and executed in a distributed fashion by the one or more processors or computers.

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents.

Therefore, in addition to the above and all drawing disclosures, the scope of the disclosure is also inclusive of the claims and their equivalents, i.e., all variations within the scope of the claims and their equivalents are to be construed as being included in the disclosure.

What is claimed is:

1. A processor-implemented method, the method comprising:
determining an estimated voltage of a battery and a surface concentration of an anode and cathode of the battery through a battery model;
determining a voltage difference between a sensed voltage of the battery and the determined estimated voltage;
determining a state variation of the battery based on the determined voltage difference and each determined surface concentration;
updating the battery model based on the determined state variation; and
determining state information of the battery based on the updated battery model.

2. The method of claim 1, wherein the determining of the state variation comprises:
determining a first open circuit potential (OCP) of the anode and the cathode using each determined surface concentration;
determining a first open circuit voltage (OCV) of the battery using each determined first OCP;
compensating each determined surface concentration based on an initial state variation;
determining a second OCP of the anode and the cathode using each compensated surface concentration;
determining a second OCV of the battery using each determined second OCP; and
determining the state variation using the determined first OCV, the determined second OCV, the initial state variation, and the determined voltage difference.

3. The method of claim 2, wherein the determining of the first OCP of the anode and the cathode comprises:
determining the first OCP of the anode and the cathode using each OCP table showing a relationship between a stoichiometric concentration and an OCP of the anode and the cathode and each determined surface concentration.

4. The method of claim 2, wherein the determining of the state variation using the determined first OCV, the determined second OCV, the initial state variation, and the determined voltage difference comprises:
determining a difference value between the determined second OCV and the determined first OCV; and
determining the state variation by applying a ratio between the determined difference value and the determined voltage difference to the initial state variation.

5. The method of claim 2, wherein the compensating of each determined surface concentration comprises:
determining each compensation value for compensating each determined surface concentration using a predetermined value for the anode and the cathode and the initial state variation; and
compensating each determined surface concentration based on each determined compensation value.

6. The method of claim 1, wherein the determining of the state variation comprises:
determining an OCP of the anode and the cathode using each determined surface concentration;
determining an OCV of the battery using each determined OCP; and
determining an optimal value of the state variation by performing an optimization operation of optimizing the state variation based on the determined voltage difference, each determined surface concentration, and the determined OCV.

7. The method of claim 6, wherein the determining of the optimal value comprises:
performing the optimization operation by adjusting a voltage difference between the determined OCV and an OCV, considering the state variation, to be the same as the determined voltage difference.

8. The method of claim 1, wherein the determining of the state variation comprises:
obtaining a first ratio value corresponding to a first determined surface concentration of a first electrode among the anode and the cathode from a first table showing a relationship between a ratio between a concentration variation and an OCP variation of the first electrode, and a concentration of the first electrode;
obtaining a second ratio value corresponding to a second determined surface concentration of a second electrode among the anode and cathode from a second table showing a relationship between a ratio between a concentration variation and an OCP variation of the second electrode, and a concentration of the second electrode; and
determining the state variation using the determined voltage difference, the obtained first ratio value, the obtained second ratio value, and an initial state variation.

9. The method of claim 8, wherein the determining of the state variation using the determined voltage difference, the obtained first ratio value, the obtained second ratio value, and the initial state variation comprises:
determining a first compensation value for compensating the surface concentration of the first electrode by applying the initial state variation to a predetermined value for the first electrode;
determining a first OCP variation value of the first electrode using the determined first compensation value and the obtained first ratio value;
determining a second compensation value for compensating the surface concentration of the second electrode by applying the initial state variation to a predetermined value for the second electrode;
determining a second OCP variation value of the second electrode using the determined second compensation value and the obtained second ratio value;
calculating a sum of the determined first OCP variation value and the determined second OCP variation value; and
determining the state variation by applying a ratio between the determined voltage difference and the calculated sum to the initial state variation.

10. The method of claim 1, wherein the updating of the battery model comprises updating an internal state of the battery model by compensating one or more of parameters of the battery model based on the determined state variation.

11. An electronic device comprising:
a battery;
at least one processor configured to execute instructions; and
a memory storing the instructions, wherein execution of the instructions causes the at least one processor to:
determine an estimated voltage of the battery and a surface concentration of an anode and a cathode of the battery through a battery model;
determine a voltage difference between a sensed voltage of the battery and the determined estimated voltage;
determine a state variation of the battery based on the determined voltage difference and each determined surface concentration;
update the battery model based on the determined state variation; and
determine state information of the battery based on the updated battery model.

12. The electronic device of claim 11, further comprising:
a voltage sensor configured to sense the battery to obtain the sensed voltage of the battery.

13. The electronic device of claim 11, wherein execution of the instructions causes the at least one processor to:
determine a first open circuit potential (OCP) of the anode and the cathode using each determined surface concentration;
determine a first open circuit voltage (OCV) of the battery using each determined first OCP;
compensate each determined surface concentration based on an initial state variation;
determine a second OCP of the anode and the cathode using each compensated surface concentration;
determine a second OCV of the battery using each determined second OCP; and
determine the state variation using the determined first OCV, the determined second OCV, the initial state variation, and the determined voltage difference.

14. The electronic device of claim 13, wherein execution of the instructions causes the at least one processor to:
determine the first OCP of the anode and the cathode using each OCP table showing a relationship between a stoichiometric concentration and an OCP of the anode and the cathode and each determined surface concentration.

15. The electronic device of claim 13, wherein execution of the instructions causes the at least one processor to:
determine a difference value between the determined second OCV and the determined first OCV; and
determine the state variation by applying a ratio between the determined difference value and the determined voltage difference to the initial state variation.

16. The electronic device of claim 13, wherein execution of the instructions causes the at least one processor to:
determine each compensation value for compensating each determined surface concentration using a predetermined value for the anode and the cathode and the initial state variation; and
compensate each determined surface concentration based on each determined compensation value.

17. The electronic device of claim 11, wherein execution of the instructions causes the at least one processor to:
obtain a first ratio value corresponding to a first determined surface concentration of a first electrode among the anode and the cathode from a first table showing a relationship between a ratio between a concentration variation and an OCP variation of the first electrode, and a concentration of the first electrode;
obtain a second ratio value corresponding to a second determined surface concentration of a second electrode among the anode and the cathode from a second table showing a relationship between a ratio between a concentration variation and an OCP variation of the second electrode, and a concentration of the second electrode; and
determine the state variation using the determined voltage difference, the obtained first ratio value, the obtained second ratio value, and the initial state variation.

18. The electronic device of claim 11, wherein execution of the instructions causes the at least one processor to:
determine an OCP of the anode and the cathode using each determined surface concentration;
determine an OCV of the battery using each determined OCP; and
determine an optimal value of the state variation by performing an optimization operation of optimizing the state variation based on the determined voltage difference, each determined surface concentration, and the determined OCV.

19. The electronic device of claim 18, wherein execution of the instructions causes the at least one processor to:
perform the optimization operation by adjusting a voltage difference between the determined OCV and an OCV, considering the state variation, to be the same as the determined voltage difference.

20. The electronic device of claim 11, wherein execution of the instructions causes the at least one processor to:
control a display such that the determined state information is displayed regarding one or more of the anode and the cathode.
